(19) United States
(12) Patent Application Publication
(10) Pub. No.: US 2020/0127141 A1
(43) Pub. Date: Apr. 23, 2020

(54) METHOD FOR MANUFACTURING THIN FILM TRANSISTOR, THIN FILM TRANSISTOR, AND DISPLAY PANEL

(71) Applicant: HKC Corporation Limited, Shenzhen (CN)

(72) Inventor: Hejing Zhang, Shenzhen (CN)

(21) Appl. No.: 16/257,080

(22) Filed: Jan. 25, 2019

Related U.S. Application Data
(63) Continuation of application No. PCT/CN2018/114464, filed on Nov. 8, 2018.

(30) Foreign Application Priority Data
Oct. 23, 2018 (CN) 201811238875.X

(51) Int. Cl. H01L 29/786; H01L 29/49; H01L 29/417; H01L 29/66; H01L 29/10

(52) U.S. Cl. CPC H01L 29/78633; H01L 29/7869; H01L 29/1033; H01L 29/41733; H01L 29/66969; H01L 29/4908

(57) ABSTRACT

The portion of the active layer of the thin film transistor, facing the gate electrode, defines a channel region, and the portions of the active layer located at two sides of the channel region are transformed to conductors.

### CROSS REFERENCE TO RELATED APPLICATIONS

The present application is a Continuation Application of PCT Application No. PCT/CN2018/114464 filed on Nov. 8, 2018, which claims the benefit of Chinese Patent Application No. 201811238875.X filed on Oct. 23, 2018. All the above are hereby incorporated by reference.

### FIELD

The exemplary embodiment of the present disclosure generally relates to the technical field of display device, and more particularly relates to a method for manufacturing thin film transistor, a thin film transistor, and a display panel.

### BACKGROUND

With the development of display technology, display panel has become one of the indispensable necessities for people. Currently, the display panel includes two kinds of display modes including an active matrix liquid crystal (AMLCD) display and an active matrix organic light emitting diode (AMOLED) display, the two display modes coexist with each other in their respective advantages. The active matrix liquid crystal display includes an active array substrate, a color filter substrate, and a liquid crystal layer between the two substrates. The active matrix organic light emitting diode display includes an active array substrate and an organic light emitting diode layer. Both display modes require a stable and reliable array substrate. The array substrate includes one or more thin film transistors (TFT). With the increasing demand for resolution and display quality of display panels, as the thin film transistor having a commonly used bottom gate structure has a relatively large parasitic capacitance, which is not conducive to high resolution and display of the organic light emitting diode (OLED). Therefore, high resolution display panels and active matrix organic light emitting diode displays often adopt thin film transistors having top gate structures.

However, during the process of manufacturing the thin film transistor with the top gate structure, the oxide semiconductor layer needs to be transformed to be conductor. But in practice, the gate electrode is directly exposed to the outside during the conducting treatment, resulting in the degeneration of the square resistance of the gate electrode or even disconnection, the resistance is large, thus affecting the electrical characteristic of the thin film transistor.

### SUMMARY

It is therefore one main object of the disclosure to provide a method for manufacturing thin film transistor, which aims to improve the electrical stability of the thin film transistor.

In order to realize the above aim, the method for manufacturing thin film transistor provided by the present disclosure includes the following operations:

providing a substrate;

coating a shading film on a surface of the substrate, and patterning the shading film to form a shading layer;

depositing a buffer layer on the shading layer;

depositing an oxide semiconductor film on the buffer layer, patterning the oxide semiconductor film to form an active layer;

depositing a gate insulating layer on the active layer;

depositing a first metal layer on the gate insulating layer, patterning the first metal layer to form a gate electrode, forming a barrier layer on the gate electrode, patterning the barrier layer to form a photoresist pattern, and etching the gate electrode and the photoresist pattern to retain portions of the gate electrode and the photoresist pattern facing the active layer; and

applying a conducting treatment to the photoresist pattern and a portion of the gate insulating layer exposed from the photoresist pattern to transform a portion of the active layer which being not facing the photoresist pattern into a conductor.

Electively, after applying the conducting treatment to the photoresist pattern and the portion of the gate insulating layer exposed from the photoresist pattern to transform the portion of the active layer which being not facing the photoresist pattern into the conductor, the method further comprises the following operations:

etching the gate insulating layer while removing the photoresist pattern;

forming an internal insulating layer on the active layer and the gate electrode, and patterning the internal insulating layer; and

depositing a second metal layer on the internal insulating layer, patterning the second metal layer to form a drain electrode and a source electrode, the drain electrode is spaced from the source electrode, two opposite sides of the active layer are transformed into conductors, and the drain electrode and the source electrode electrically connect to the conductors on two sides respectively.

Electively, when the shielding layer is a conductive material, patterning the buffer layer and the internal insulating layer to allow the source electrode to electrically connect with the shielding layer.

Electively, the method further comprises:

forming a passivation layer is formed on the source electrode and drain electrode, forming a pixel electrode on the passivation layer, and one end of the pixel electrode electrically connects to the source electrode through a contact hole.

Electively, the barrier layer has a thickness of 1.5 micrometers to 2.5 micrometers.

The present disclosure further provides a thin film transistor, which is manufactured by a method for manufacturing thin film transistor, the method comprising the following operations:

providing a substrate;

coating a shading film on a surface of the substrate, and patterning the shading film to form a shading layer;

depositing a buffer layer on the shading layer;

depositing an oxide semiconductor film on the buffer layer, patterning the oxide semiconductor film to form an active layer;

depositing a gate insulating layer on the active layer;

depositing a first metal layer on the gate insulating layer, patterning the first metal layer to form a gate electrode, forming a barrier layer on the gate electrode, patterning the barrier layer to form a photoresist pattern, and etching the gate electrode and the photoresist pattern to retain portions of the gate electrode and the photoresist pattern facing the active layer; and

applying a conducting treatment to the photoresist pattern and a portion of the gate insulating layer exposed from the photoresist pattern to transform a portion of the active layer which being not facing the photoresist pattern into a conductor;

thin film transistor includes:

the substrate;

the shading layer, defined on the substrate;

the buffer layer, defined on the shading layer;

the active layer, defined on the buffer layer;

the gate insulating layer, defined on the active layer;

the gate electrode, defined on the gate insulating layer; and

the portion of active layer facing the gate electrode defines a channel region, the portion at two sides of the channel region is transformed to be a conductor.

Electively, the thin film transistor further comprises:

an internal insulating layer, covering the gate electrode, the active layer, and the buffer layer;

a source electrode, defined on the inner insulation layer; and

a drain electrode, defined on the internal insulation layer and spaced from the source electrode, and the drain electrode and the source electrode electrically connect to the conductors at two sides of the active layer through contact holes respectively.

Electively, the thin film transistor further comprises a passivation layer covering the internal insulating layer, the source electrode and the drain, and a pixel electrode defined on the passivation layer, the pixel electrode electrically connects to the source electrode through a contact hole.

Electively, the gate insulating layer has a thickness of 500 Åto 3000 Å.

The present disclosure further provides a display panel, the display panel includes a thin film transistor, the thin film transistor is manufactured by a method for manufacturing thin film transistor, the method includes the following operations:

providing a substrate;

coating a shading film on a surface of the substrate, and patterning the shading film to form a shading layer;

depositing a buffer layer on the shading layer;

depositing an oxide semiconductor film on the buffer layer, patterning the oxide semiconductor film to form an active layer;

depositing a gate insulating layer on the active layer;

depositing a first metal layer on the gate insulating layer, patterning the first metal layer to form a gate electrode, forming a barrier layer on the gate electrode, patterning the barrier layer to form a photoresist pattern, and etching the gate electrode and the photoresist pattern to retain portions of the gate electrode and the photoresist pattern facing the active layer; and

applying a conducting treatment to the photoresist pattern and a portion of the gate insulating layer exposed from the photoresist pattern to transform a portion of the active layer which being not facing the photoresist pattern into a conductor;

wherein, thin film transistor comprises:

the substrate;

the shading layer, defined on the substrate;

the buffer layer, defined on the shading layer;

the active layer, defined on the buffer layer;

the gate insulating layer, defined on the active layer;

the gate electrode, defined on the gate insulating layer; and

the portion of active layer facing the gate electrode defines a channel region, the portion at two sides of the channel region is transformed to be a conductor.

For the thin film transistor of the present disclosure, the barrier layer is formed on the gate electrode, the barrier layer is patterned to form the photoresist pattern, the gate electrode and the photoresist pattern are etched, the portions of the gate electrode and the photoresist pattern facing the active layer are reserved, the photoresist pattern and the gate insulation layer exposed from the photoresist pattern are subjected to conducting treatment, such the portion of the active layer which is not facing the photoresist pattern is converted into a conductor. Because the barrier layer is arranged on the outer surface of the gate electrode, damage to the gate electrode during conducting process can be effectively prevented, so that the square resistance of the gate electrode is prevented from becoming larger, and, the active layer can be well conducted, the impedance is reduced, so that the overall electrical performance of the thin film transistor is stable

### BRIEF DESCRIPTION OF THE DRAWINGS

To better illustrate the technical solutions that are reflected in various embodiments according to this disclosure or that are found in the prior art, the accompanying drawings intended for the description of the embodiments herein or for the prior art will now be briefly described, it is evident that the accompanying drawings listed in the following description show merely some embodiments according to this disclosure, and that those having ordinary skill in the art will be able to obtain other drawings based on the arrangements shown in these drawings without making inventive efforts.

FIG. 1 is a diagram of forming the shielding layer in the method for manufacturing thin film transistor of the present disclosure;

FIG. 2 is a diagram of forming the buffer layer and the active layer in the method for manufacturing thin film transistor of the present disclosure;

FIG. 3 is a diagram of forming the gate insulating layer, the gate electrode and the barrier layer in the method for manufacturing thin film transistor of the present disclosure;

FIG. 4 is a diagram of forming conductor in the method for manufacturing thin film transistor of the present disclosure;

FIG. 5 is a diagram of etching the gate insulating layer and removing the photoresist pattern in the method for manufacturing thin film transistor of the present disclosure;

FIG. 6 is a diagram of forming the drain electrode, the source electrode, and the pixel electrode in the method for manufacturing thin film transistor of the present disclosure according to some embodiments;

FIG. 7 is a diagram of forming the drain electrode, the source electrode, and the pixel electrode in the method for manufacturing thin film transistor of the present disclosure according to another embodiment.

Labels illustration for drawings:

| Label | Name |
|---|---|
| 10 | substrate |
| 20 | shading layer |
| 30 | buffer layer |
| 40 | active layer |
| 41 | first conductor |
| 42 | second conductor |
| 43 | channel region |
| 50 | gate insulating layer |
| 60 | gate electrode |
| 70 | barrier layer |
| 80 | internal insulating layer |
| 90 | drain electrode |
| 100 | source electrode |
| 110 | passivation layer |
| 120 | pixel electrode |

The realization of the aim, functional characteristics, advantages of the present disclosure are further described specifically with reference to the accompanying drawings and embodiments.

### DETAILED DESCRIPTION

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present invention without creative efforts shall fall within the protection scope of the present invention.

It is to be understood that, all of the directional instructions in the exemplary embodiments of the present disclosure (such as top, down, left, right, front, back . . . ) can only be used for explaining relative position relations, moving condition of the elements under a special form (referring to figures), and so on, if the special form changes, the directional instructions changes accordingly.

It should be further noted that in depictions of the present disclosure, terms such as “connect” should be understood in a broad sense, unless otherwise prescribed or defined explicitly. In other words, the connection can be a fixed connection, a removable connection or an integral connection. Of course, the connection can also be a direct connection, an indirect connection via an intermediary, or an internal communication between two elements. For a person having ordinary skills in the art, he/she can understand specific meanings of the above terms in the present disclosure upon specific situations.

In addition, the descriptions, such as the “first”, the “second” in the present disclosure, can only be used for describing the aim of description, and cannot be understood as indicating or suggesting relative importance or impliedly indicating the number of the indicated technical character. Therefore, the character indicated by the “first”, the “second” can express or impliedly include at least one character. In addition, the technical proposal of each exemplary embodiment can be combined with each other, however the technical proposal must base on that the ordinary skill in that art can realize the technical proposal, when the combination of the technical proposals occurs contradiction or cannot realize, it should consider that the combination of the technical proposals does not existed, and is not contained in the protection scope required by the present disclosure.

The present disclosure provides a method for manufacturing a thin film transistor.

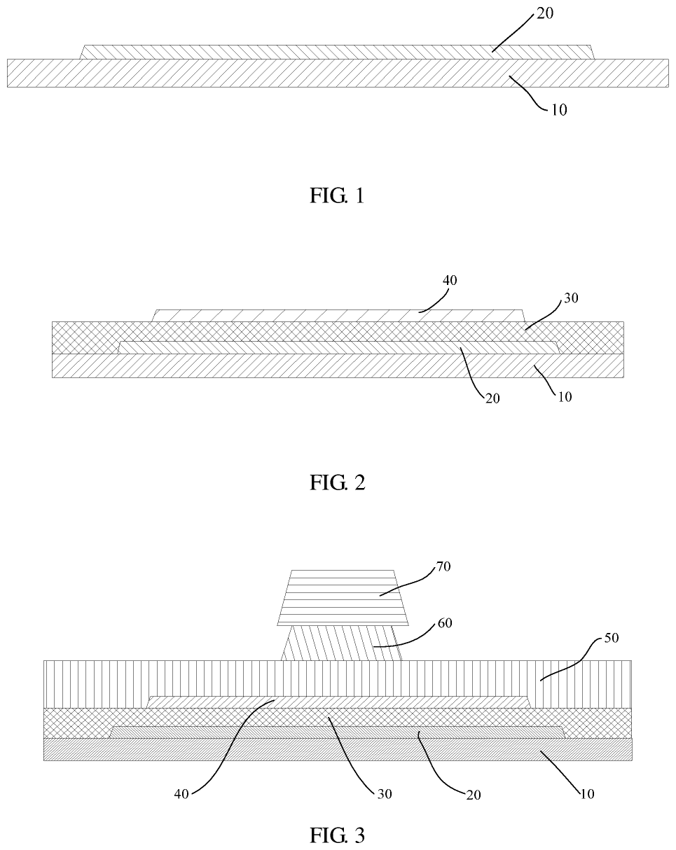

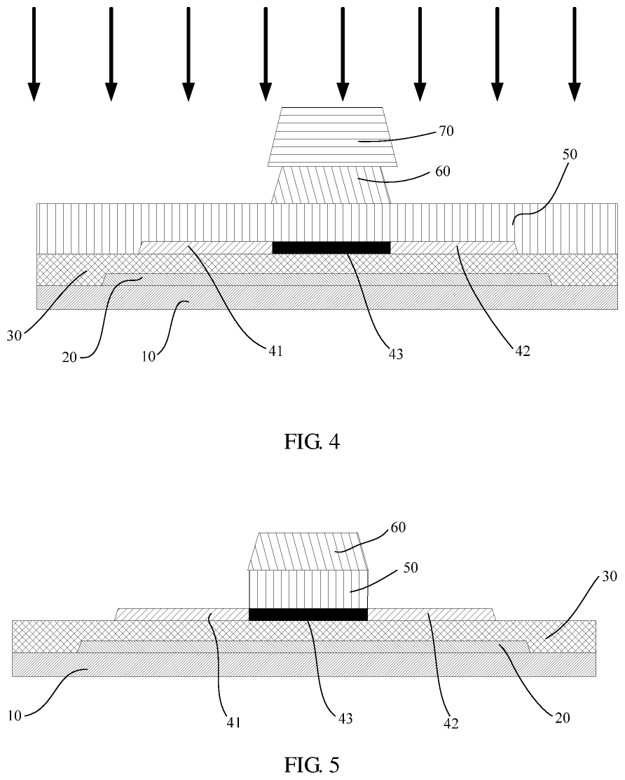

Referring to FIGS. 1 to 4, in some embodiments of the present disclosure, the method for manufacturing thin film transistor includes the following steps:

providing a substrate 10;

coating a shading film on a surface of the substrate 10, and patterning the shading film to form a shading layer 20;

depositing a buffer layer 30 on the shading layer 20;

depositing an oxide semiconductor film on the buffer layer 30, patterning the oxide semiconductor film to form an active layer 40;

depositing a gate insulating layer 50 on the active layer 40;

depositing a first metal layer on the gate insulating layer 50, patterning the first metal layer to form a gate electrode 60, forming a barrier layer 70 on the gate electrode 60, patterning the barrier layer 70 to form a photoresist pattern, and etching the gate electrode and the photoresist pattern to retain portions of the gate electrode 60 and the photoresist pattern facing the active layer 40; and

applying a conducting treatment to the photoresist pattern and a portion of the gate insulating layer 50 exposed from the photoresist pattern to transform a portion of the active layer 40 which is not facing the photoresist pattern into a conductor.

Specifically, the substrate 10 is an insulating substrate whose light transmittance of external light exceeds a preset light transmittance, and the preset light transmittance may be, but is not limited to, 90%. The material of the substrate 10 includes any one or more of electrically insulating materials such as quartz, mica, alumina, or transparent plastic, etc. The substrate 10 is an insulating layer substrate capable of reducing its high frequency loss.

A shielding film is coated on one surface of the substrate 10, and the shielding film is patterned to form a shielding layer 20 which may be an organic (e.g., BM, acrylic resin) or inorganic (e.g., metal Mo, Ti, etc.) material. The shielding layer 20 can shield ultraviolet light passing through the substrate 10 so that ultraviolet light passing through the substrate 10 cannot pass through.

The buffer layer 30 is deposited on the shielding layer 20. Specifically, the buffer layer 30 is deposited on the surface of the shielding layer 20 away from the substrate 10 by chemical vapor deposition. The buffer layer 30 may include silicon nitride, silicon oxide, silicon oxynitride, silicon carbide, aluminum oxide, or hafnium oxide, respectively. The light leakage current of the thin film transistor can be reduced by increasing the light reflectivity of the contact surface between the buffer layer 30 and the active layer 40. The thickness of the buffer layer 30 is not the main improvement point of the present disclosure, and will not be described in detail here.

The oxide semiconductor thin film is deposited on the buffer layer 30, specifically, the oxide semiconductor thin film is deposited on the surface of the buffer layer 30 away from the shielding layer 20 by chemical vapor deposition, and the oxide semiconductor thin film is patterned to form the active layer 40. The active layer 40 is also referred to as a channel layer. In some embodiments, the active layer 40 is a metal oxide semiconductor layer which may include, but is not limited to, one or more of the following materials: ZnO based transparent oxide semiconductor material, SnO₂ based transparent oxide semiconductor material, In₂O₃ based transparent oxide semiconductor material, etc. For example, the active layer 170 may be indium gallium zinc oxide (IGZO).

The gate insulating layer 50 is deposited on the active layer 40. Specifically, the gate insulating layer 50 is deposited by chemical vapor deposition on the surface of the active layer 40 away from the buffer layer 30. The gate insulating layer 50 may be made of silicon oxide (SiO₂) material. In some embodiments, the thickness of the gate insulating layer 50 is 500 Å to 3000 Å. Electively, the thickness of the gate insulating layer 50 is 500Å, 1000 Å, or 3000 Å. When the thickness of the gate insulating layer 50 is less than 500 Å, its thickness is too small to improve the electrical performance of the active layer 40. When the thickness of the gate insulating layer 50 is greater than 3000 Å, the thicker gate insulating layer 50 will obviously conducting affect of the active layer 40. Therefore, it is more appropriate to set the gate insulating layer 50 has the thickness of 500 Åto 3000 Å.

Depositing a first metal layer is on the gate insulating layer 50, patterning the first metal layer to form the gate electrode 60, forming a barrier layer 70 on the gate electrode 60, patterning the barrier layer 70 to form a photoresist pattern, and etching the gate electrode 60 and the photoresist pattern to retain the portions of the gate electrode 60 and the photoresist pattern facing the active layer 40, specifically, depositing the first metal layer on the surface of the gate insulating layer 50 away from the active layer 40 by physical vapor deposition, patterning the first metal layer to form the gate electrode 60, and the gate electrode 60 is made of a metal material with excellent conductivity and good light shielding property. The gate electrode 60 can block light to prevent light from entering the portion of the active layer 40 which is blocked by the gate electrode 60 when conducting, so that the thin film transistor has good electrical stability. The material of the gate electrode 60 can be selected one or more from a group consisting of molybdenum (Mo), aluminum (Al), copper (Cu), and titanium (Ti). Forming the barrier layer 70 on the surface of the gate 60 away from the gate insulating layer 50 by chemical vapor deposition, and the barrier layer 70 is a photosensitive substance. The gate electrode 60 and the photoresist pattern are etched by a wet etching process to remove the portion of the gate electrode 60 exposed from the photoresist pattern.

Conducting the portions of the photoresist pattern and the gate insulating layer 50 exposed from the photoresist pattern to convert the portion of the active layer 40 that is not facing the photoresist pattern into a conductor. Specifically, the conducting treatment method is a plasma treatment method, an ion implantation treatment method, an ultraviolet irradiation treatment method, or a microwave treatment method. The two opposite sides of the active layer 40, i.e., the left and right portions of the active layer 40 in FIGS. 4 to 6, have conductivity, that is the first conductor 41 and the second conductor 42 in the figure. The lengths of the first conductor 41 and the second conductor 42 may be the same or different, and the lengths of the conductors on both sides may be 5 micrometers to 25 micrometers.

For the thin film transistor of the present disclosure, the barrier layer 70 is formed on the gate electrode 60, patterned to form the photoresist pattern, and the gate electrode 60 and photoresist pattern 70 are etched, thereby leaving the portions of the gate electrode 60 and photoresist pattern facing the active layer 40, the photoresist pattern and the gate insulating layer 50 exposed from the photoresist pattern are treated by the conducting treatment to convert the portion of the active layer 40 not facing the photoresist pattern into a conductor. Since the barrier layer 70 is provided on the outer surface of the gate electrode 60, damage to the gate electrode 60 during conducting treatment can be effectively prevented, the box resistance of the gate electrode 60 is prevented from increasing, and the active layer 40 can be well conducted at the same time, the impedance is reduced, such the overall electrical performance of thin film transistors is stable.

Referring to FIGS. 5 to 7, after applying the conducting treatment to the photoresist pattern and the portion of the gate insulating layer 50 exposed from the photoresist pattern to transform the portion of the active layer 40 which is not facing the photoresist pattern into the conductor, the method further includes the following operations:

etching the gate insulating layer 50 while removing the photoresist pattern;

forming an internal insulating layer 80 on the active layer 40 and the gate electrode 60, and patterning the internal insulating layer 80; and

depositing a second metal layer on the internal insulating layer 80, patterning the second metal layer to form a drain electrode 90 and a source electrode 100, the drain electrode 90 is spaced from the source electrode 100, two opposite sides of the active layer 40 are transformed into conductors, and the drain electrode 90 and the source electrode 100 electrically connect to the conductors on two sides respectively.

In some embodiments, the gate insulating layer 50 is etched by the wet etching process while removing the photoresist pattern, and the internal insulating layer 80 is formed on the surfaces of the active layer 40 and the gate 60 away from the buffer layer 30. The internal insulating layer 80 can be directly coated or formed by chemical vapor deposition method, the present disclosure does not limit this, the internal insulating layer 80 can be a silicon oxide (SiO₂) film or a composite film of silicon oxide (SiO₂) and silicon nitride (SiNₓ), the silicon oxide layer is adjacent to the active layer 40 and the silicon nitride layer is away from the active layer 40.

The second metal layer is deposited on the surface of the internal insulating layer 80 away from the active layer 40 by physical vapor deposition, and the second metal layer is patterned to form the drain electrode 90 and the source electrode 100, the drain electrode 90 and the source electrode 100 are spaced from each other, opposite sides of the active layer 40 are converted into conductors, and the drain electrode 90 and the source electrode 100 are electrically connected to the conductors at two sides, that is, the first conductor 41 is electrically connected to the drain electrode 90, and the second conductor 42 is electrically connected to the source electrode 100. Since the opposite sides of the active layer 40 have good conductivity, it is advantageous to achieve good conductive contact between the source electrode 100 and one side of the active layer 40, and between the drain electrode 90 and the other opposite side of the active layer 40, which can not only reduce the contact resistances between the source electrode 100 and one side of the active layer 40, and between the drain electrode 90 and the other opposite side of the active layer 40, but also can reduce the risk of current leakage.

The source electrode 100 and drain electrode 90 may be made of a transparent conductive oxide film layer which includes, but not limited to, indium tin oxide (ITO), indium zinc oxide (IZO), fluorine-doped tin oxide (SnO₂:F, FTO) and aluminum-doped zinc oxide (ZnO:Al, AZO).

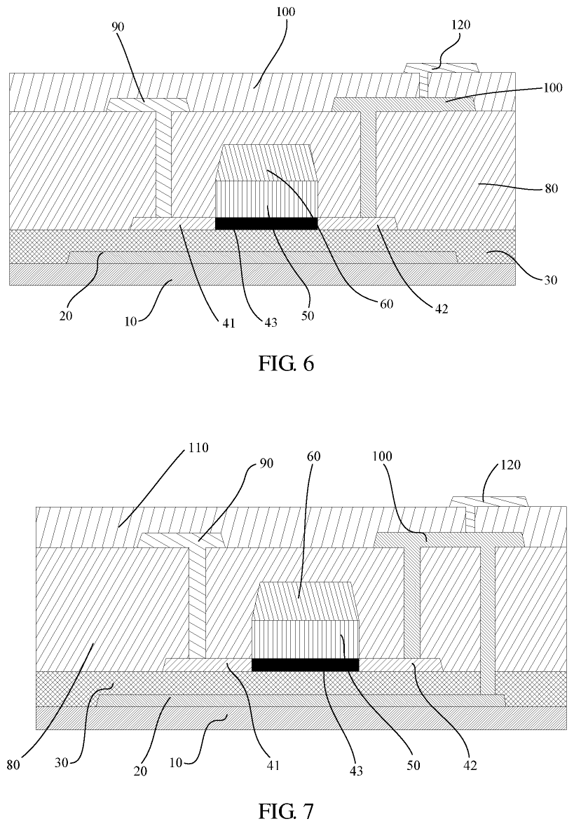

Referring to FIGS. 6 and 7, when the shielding layer 20 is a conductive material, the buffer layer 30 and the internal insulating layer 80 are patterned to electrically connect the source electrode 100 with the shielding layer 20.

In some embodiments, as shown in FIG. 7, when the shielding layer 20 is the conductive material, the buffer layer 30 and the internal insulating layer 80 are patterned to electrically connect the source electrode 100 with the shielding layer 20, which can improve the electrical stability of the thin film transistor. In another embodiment, as shown in FIG. 6, if the shielding layer 20 is a non-conductive material, only the internal insulating layer 80 needs to be patterned.

Further, the method for manufacturing thin film transistor further includes:

A passivation layer 110 is formed on the source electrode 100 and the drain electrode 90, a pixel electrode 120 is formed on the passivation layer 110, and one end of the pixel electrode 120 is electrically connected to the source electrode 100 through a contact hole.

In some embodiments, the passivation layer 110 is formed on the surfaces of the source electrode 100 and the drain electrode 90 away from the internal insulating layer 80, and the passivation layer 110 may be directly coated the surfaces or may be formed by by chemical vapor deposition, the passivation layer 110 and the internal insulating layer 80 may be made of the same or different materials. The passivation layer 100 may be a silicon oxide (SiO₂) film, or the passivation layer 100 may be a composite film of silicon oxide (SiO₂) film and silicon nitride (SiNₓ) film.

The pixel electrode 120 may be a translucent electrode or a reflective electrode. When the pixel electrode 120 is a translucent electrode, the pixel electrode 120 may include a transparent conductive layer. For example, The transparent conductive layer may be selected at least one from a group consisting of indium tin oxide (ITO), indium zinc oxide (IZO), zinc oxide (ZnO), indium oxide (In₂O₃), indium gallium oxide (IGO), and aluminum zinc oxide (AZO). In addition to the transparent conductive layer, the pixel electrode 120 may also include a transflective layer arranged to improve the luminous efficiency. The transflective layer may be a thin layer (e.g., which has a thickness of several nanometers to tens of nanometers) and may be selected at least one from a group consisting of Ag, Mg, Al, Pt, Pd, Au, Ni, Nd, IR, Cr, Li, Ca, and Yb, without limitation here.

Furthermore, the thickness of the barrier layer 70 is 1.5 micrometers to 2.5 micrometers. The thickness of the optional barrier layer 70 can be 1.5 micrometers, 2 micrometers, 2.5 micrometers.

In some embodiments, the thickness of the barrier layer 70 directly affects the conducting effect the active layer 40, when the thickness of the barrier layer 70 is less than 1.5 micrometers, the electrical performance of the thin film transistor is unstable during the conducting process. When the thickness of the barrier layer 70 is greater than 2.5 micrometers, the material is wasted, which is not conducive to cost saving. Therefore, it is more appropriate to set the barrier layer 70 have the thickness of 1.5 micrometers to 2.5 micrometers.

The present disclosure also provides a thin film transistor which is manufactured by the method for manufacturing thin film transistor. the specific structure of the thin film transistor is referred to the above-mentioned embodiments. As the thin film transistor provided by the present disclosure adopts all the technical proposals of the above exemplary embodiments, the thin film transistor at least has all of the beneficial effects of the technical proposals of the above exemplary embodiments, no need to repeat again.

thin film transistor includes:

a substrate 10;

a shading layer 20, defined on the substrate 10;

a buffer layer 30, defined on the shading layer 20;

a active layer 40, defined on the buffer layer 30;

a gate insulating layer 50, defined on the active layer 40;

a gate electrode 60, defined on the gate insulating layer 50; and

a portion of active layer 40 facing the gate electrode 60 defines a channel region 43, the portion at two sides of the channel region 43 is transformed to be a conductor.

Furthermore, the thin film transistor further includes:

an internal insulating layer 80, covering the gate electrode 60, the active layer 40, and the buffer layer 30;

a source electrode 100, defined on the inner insulation layer 80; and

a drain electrode 90, defined on the internal insulation layer 80 and spaced from the source electrode 100, and the drain electrode 90 and the source electrode 100 electrically connect to the conductors at two sides of the active layer 40 through contact holes respectively.

Furthermore, the thin film transistor further includes a passivation layer 110 covering the internal insulating layer 80, the source electrode 100 and the drain electrode 90, and a pixel electrode 120 disposed on the passivation layer 110, and the pixel electrode 120 is electrically connected to the source electrode 100 through a contact hole.

In some embodiments, the portions of the active layer 40 at two sides of the channel region 43 are transformed to be conductors, that is, the first conductor 41 and the second conductor 42 are formed on two sides of the active layer 40.

The present disclosure also provides a display panel, the display panel includes a thin film transistor, the specific structure of the thin film transistor is referred to the above-mentioned embodiments. As the display panel provided by the present disclosure adopts all the technical proposals of the above exemplary embodiments, the display panel at least has all of the beneficial effects of the technical proposals of the above exemplary embodiments, no need to repeat again.

The foregoing description merely depicts some embodiments of the present disclosure and therefore is not intended to limit the scope of the application. An equivalent structural or flow changes made by using the content of the specification and drawings of the present disclosure, or any direct or indirect applications of the disclosure on any other related fields shall all fall in the scope of the application.

What is claimed is:

1. A method for manufacturing thin film transistor, comprising the following operations:
providing a substrate;
coating a shading film on a surface of the substrate, and patterning the shading film to form a shading layer;
depositing a buffer layer on the shading layer;
depositing an oxide semiconductor film on the buffer layer, patterning the oxide semiconductor film to form an active layer;
depositing a gate insulating layer on the active layer;
depositing a first metal layer on the gate insulating layer, patterning the first metal layer to form a gate electrode, forming a barrier layer on the gate electrode, patterning the barrier layer to form a photoresist pattern, and etching the gate electrode and the photoresist pattern to retain portions of the gate electrode and the photoresist pattern facing the active layer; and
applying a conducting treatment to the photoresist pattern and a portion of the gate insulating layer exposed from the photoresist pattern to transform a portion of the active layer which being not facing the photoresist pattern into a conductor.

2. The method according to claim 1, wherein after applying the conducting treatment to the photoresist pattern and the portion of the gate insulating layer exposed from the photoresist pattern to transform the portion of the active layer which being not facing the photoresist pattern into the conductor, the method further comprises the following operations:
etching the gate insulating layer while removing the photoresist pattern;
forming an internal insulating layer on the active layer and the gate electrode, and patterning the internal insulating layer; and
depositing a second metal layer on the internal insulating layer, patterning the second metal layer to form a drain electrode and a source electrode, the drain electrode is spaced from the source electrode, two opposite sides of the active layer are transformed into conductors, and the drain electrode and the source electrode electrically connect to the conductors on two sides respectively.

3. The method according to claim 2, wherein when the shielding layer is a conductive material, patterning the buffer layer and the internal insulating layer to allow the source electrode to electrically connect with the shielding layer.

4. The method according to claim 2, wherein the method further comprises:
forming a passivation layer is formed on the source electrode and drain electrode, forming a pixel electrode on the passivation layer, and one end of the pixel electrode electrically connects to the source electrode through a contact hole.

5. The method according to claim 1, wherein the barrier layer has a thickness of 1.5 micrometers to 2.5 micrometers.

6. A thin film transistor, manufactured by a method for manufacturing thin film transistor, the method comprising the following operations:
providing a substrate;
coating a shading film on a surface of the substrate, and patterning the shading film to form a shading layer;
depositing a buffer layer on the shading layer;
depositing an oxide semiconductor film on the buffer layer, patterning the oxide semiconductor film to form an active layer;
depositing a gate insulating layer on the active layer;
depositing a first metal layer on the gate insulating layer, patterning the first metal layer to form a gate electrode, forming a barrier layer on the gate electrode, patterning the barrier layer to form a photoresist pattern, and etching the gate electrode and the photoresist pattern to retain portions of the gate electrode and the photoresist pattern facing the active layer; and
applying a conducting treatment to the photoresist pattern and a portion of the gate insulating layer exposed from the photoresist pattern to transform a portion of the active layer which being not facing the photoresist pattern into a conductor;
wherein, thin film transistor comprises:
the substrate;
the shading layer, defined on the substrate;
the buffer layer, defined on the shading layer;
the active layer, defined on the buffer layer;
the gate insulating layer, defined on the active layer;
the gate electrode, defined on the gate insulating layer; and
the portion of active layer facing the gate electrode defines a channel region, the portion at two sides of the channel region is transformed to be a conductor.

7. The thin film transistor according to claim 6, wherein after applying the conducting treatment to the photoresist pattern and the portion of the gate insulating layer exposed from the photoresist pattern to transform the portion of the active layer which being not facing the photoresist pattern into the conductor, the method further comprises the following operations:
etching the gate insulating layer while removing the photoresist pattern;
forming an internal insulating layer on the active layer and the gate electrode, and patterning the internal insulating layer; and
depositing a second metal layer on the internal insulating layer, patterning the second metal layer to form a drain electrode and a source electrode, the drain electrode is spaced from the source electrode, two opposite sides of the active layer are transformed into conductors, and the drain electrode and the source electrode electrically connect to the conductors on two sides respectively.

8. The thin film transistor according to claim 7, wherein when the shielding layer is a conductive material, patterning the buffer layer and the internal insulating layer to allow the source electrode to electrically connect with the shielding layer.

9. The thin film transistor according to claim 7, wherein the method further comprises:
forming a passivation layer is formed on the source electrode and drain electrode, forming a pixel electrode on the passivation layer, and one end of the pixel electrode electrically connects to the source electrode through a contact hole.

10. The thin film transistor according to claim 6, wherein the barrier layer has a thickness of 1.5 micrometers to 2.5 micrometers.

11. The thin film transistor of claim 6, wherein the thin film transistor further comprises:
an internal insulating layer, covering the gate electrode, the active layer, and the buffer layer;
a source electrode, defined on the inner insulation layer; and
a drain electrode, defined on the internal insulation layer and spaced from the source electrode, and the drain electrode and the source electrode electrically connect to the conductors at two sides of the active layer through contact holes respectively.

12. The thin film transistor according to claim 11, wherein the thin film transistor further comprises a passivation layer covering the internal insulating layer, the source electrode and the drain, and a pixel electrode defined on the passivation layer, the pixel electrode electrically connects to the source electrode through a contact hole.

13. The thin film transistor according to claim 6, wherein the gate insulating layer has a thickness of 500 Å to 3000 Å.

14. A display panel, wherein, the display panel comprises a thin film transistor, the thin film transistor is manufactured by a method for manufacturing thin film transistor, the method comprises the following operations:
providing a substrate;
coating a shading film on a surface of the substrate, and patterning the shading film to form a shading layer;
depositing a buffer layer on the shading layer;
depositing an oxide semiconductor film on the buffer layer, patterning the oxide semiconductor film to form an active layer;
depositing a gate insulating layer on the active layer;
depositing a first metal layer on the gate insulating layer, patterning the first metal layer to form a gate electrode, forming a barrier layer on the gate electrode, patterning the barrier layer to form a photoresist pattern, and etching the gate electrode and the photoresist pattern to retain portions of the gate electrode and the photoresist pattern facing the active layer; and
applying a conducting treatment to the photoresist pattern and a portion of the gate insulating layer exposed from the photoresist pattern to transform a portion of the active layer which being not facing the photoresist pattern into a conductor;
wherein, thin film transistor comprises:
the substrate;
the shading layer, defined on the substrate;
the buffer layer, defined on the shading layer;
the active layer, defined on the buffer layer;
the gate insulating layer, defined on the active layer;
the gate electrode, defined on the gate insulating layer; and
the portion of active layer facing the gate electrode defines a channel region, the portion at two sides of the channel region is transformed to be a conductor.

15. The display panel according to claim 14, wherein the thin film transistor further comprises:
an internal insulating layer, covering the gate electrode, the active layer, and the buffer layer;
a source electrode, defined on the inner insulation layer; and
a drain electrode, defined on the internal insulation layer and spaced from the source electrode, and the drain electrode and the source electrode electrically connect to the conductors at two sides of the active layer through contact holes respectively.

16. The thin film transistor according to claim 15, wherein the thin film transistor further comprises a passivation layer covering the internal insulating layer, the source electrode and the drain, and a pixel electrode defined on the passivation layer, the pixel electrode electrically connects to the source electrode through a contact hole.

17. The thin film transistor according to claim 14, wherein the gate insulating layer has a thickness of 500 Å to 3000 Å.
